(19) United States
(12) Patent Application Publication
(10) Pub. No.: US 2008/0277774 A1
(43) Pub. Date: Nov. 13, 2008

(54) POWER SEMICONDUCTOR DEVICE, ELECTRONIC DEVICE, LEAD FRAME MEMBER, AND METHOD OF MAKING POWER SEMICONDUCTOR DEVICE

(76) Inventor: Yasushi HASEGAWA, Nara (JP)

Correspondence Address: BIRCH STEWART KOLASCH & BIRCH, PO BOX 747, FALLS CHURCH, VA, 22040-0747, US

(21) Appl. No.: 12/110,739

(22) Filed: Apr. 28, 2008

(30) Foreign Application Priority Data
May 8, 2007 (JP) 2007-123660

(51) Int. Cl. H01L 23/48; H01L 21/00

(52) U.S. Cl. 257/693; 438/123; 257/E23.01

(57) ABSTRACT

The power semiconductor device according to the present invention comprises a power element, a package encapsulating the power element with resin, a power element mounting portion used for mounting the power element, and a plurality of lead pins brought out of the package, including a power element lead pin brought out of the power element mounting portion. The power semiconductor device comprises a heat dissipating member having, adjacent the power element lead pin, a heat dissipating lead pin integrally connected to the power element lead pin and heat dissipating portion integrally connected to the heat dissipating lead pin.

This application claims priority under 35 U.S.C. §119(a) on Japanese Patent Application No. 2007-123660 filed in Japan on May 8, 2007, the entire contents of which are herein incorporated by reference.

### BACKGROUND OF THE INVENTION

1. Field of the Invention

The present invention relates to a power semiconductor device, such as a solid state relay, which comprises triac elements, thyristor elements, and other power elements, to an electronic device and a lead frame member equipped therewith, and to a method of making the power semiconductor device.

2. Description of the Related Art

A solid state relay comprising a light-emitting element converting electrical signals into optical signals, a light-receiving element converting optical signals from the light-emitting element into electrical signals, a power element connected to the light-receiving element, and a package that encapsulates the light-emitting element and light-receiving element with resin together with the power element such that the light-emitting element and light-receiving element are optically coupled, can be suggested as an example of a conventional power semiconductor device comprising a power element, such as a triac element, a thyristor element, and the like.

In such a conventional power semiconductor device, the temperature rise associated with conduction through the power element results in problems such as impaired characteristics, reduced reliability, etc. Accordingly, various approaches have been tried to improve its heat-dissipative effects. Below, explanations are provided using a DIP (Dual Inline Package)-type solid state relay as an example.

FIGS. 14a and 14b are diagrams illustrating an exemplary internal structure of a conventional DIP-type solid state relay, with FIG. 14a being a schematic see-through view of the solid state relay as viewed from the side, and FIG. 14b being a schematic see-through view of the solid state relay as viewed in plan view.

As shown in FIGS. 14a and 14b, a solid state relay A has an internal structure, in which a light-emitting element (e.g. a light-emitting diode) 83 is arranged on an input-side lead frame 60a while a light-receiving element 82 is arranged on a receive-side lead frame 60b in an optically coupled relationship to the light-emitting element, with a triac element 81, which is an example of a power element, arranged on a power element mounting portion. In the thus configured solid state relay A, the driving of a load, such as an external motor, is controlled based on controlling conduction between lead pins T71 and T72 connected to the triac element 81 by switching optical signals fed from the light-emitting element 83 to the light-receiving element 82 ON and OFF.

The current that flows through the triac element 81 causes the triac element 81 to generate heat and raises its junction temperature (temperature at junctions) which, if left unaddressed, impairs characteristics and reduces reliability.

Accordingly, conventional solid state relays include configurations, in which, as shown in FIGS. 15a and 15b, the temperature rise is minimized by providing heat dissipating pins E, F on the outer surface of the solid state relay main body B so as to dissipate the heat of the triac element 81 outside through these heat dissipating pins E, F.

It should be noted that in such cases the heat dissipating pins are constituted by external lead wires, which are arranged in a mutually isolated and separate relationship for connection to any element within the main body of the solid state relay. Moreover, there also are solid state relays, in which the width of the heat dissipating pins is extended in order to impart heat-dissipative effects to a portion of the lead frame (see JP H06-232720A), and solid state relays whose heat-dissipative effects are increased by exposing heat dissipating pins on the top face (or bottom face) of the package.

On the other hand, in a SIP (Single Inline Package)-type solid state relay, its heat dissipating effects are improved by threading a heat dissipating plate into a through-hole formed in advance in the package (see JP S61-174748U, JP E03-109346U, and JP H04-020245U).

Incidentally, in general, the higher the effective “on” current that flows through the triac element, the wider the field of application of the solid state relay. For this reason, it is desirable to allow the maximum possible effective “on” current to flow.

On the other hand, the effective “on” current relates to the ambient temperature as shown in FIG. 16. Namely, due to the thermal resistance Rₜₕ₍ⱼ₋ₐ₎ of the solid state relay main body package, the effective “on” current Iₜ flowing in the operating temperature range of the triac element exhibits the derating characteristics illustrated in FIG. 16. According to the diagram, when the ambient temperature Tₐ exceeds a certain temperature t₁, the effective “on” current Iₜ drops and, as a result, a large effective “on” current can no longer pass on the high-temperature side of the diagram.

Accordingly, in order to allow a large effective “on” current to pass on the high-temperature side, it is necessary to shift the temperature, at which the effective “on” current starts to drop, toward higher temperatures in the diagram by reducing the thermal resistance Rₜₕ₍ⱼ₋ₐ₎ of the package, in other words, by increasing its heat-dissipative capabilities.

However, the heat-dissipative capabilities of conventional solid state relays such as the one described above are insufficient. In other words, a need exists for an improvement in characteristics based on increasing the heat-dissipative capabilities.

### SUMMARY OF THE INVENTION

The present invention was made with account taken of the above circumstances and it is an object of the invention to provide a power semiconductor device and an electronic device equipped with the power semiconductor device, the power semiconductor device comprising a power element and a package encapsulating the power element with resin, that are structurally simple and inexpensive and allow for increasing the heat-dissipative capabilities over the prior art and thus make it possible to achieve an improvement in characteristics.

Moreover, it is an object of the present invention to provide a method of making a power semiconductor device and a lead frame member, whereby a structurally simple and inexpensive power semiconductor device can be obtained that allows for increasing the heat-dissipative capabilities over the prior art and thus makes it possible to achieve an improvement in characteristics.

The power semiconductor device of the present invention is a power semiconductor device comprising a power element, a package encapsulating the power element with resin, a power element mounting portion used for mounting the power element, and a plurality of lead pins brought out of the package, including a power element lead pin brought out of the power element mounting portion, with the power semiconductor device comprising a heat dissipating member having, adjacent the power element lead pin, a heat dissipating lead pin integrally connected to the power element lead pin and a heat dissipating portion integrally connected to the heat dissipating lead pin.

In accordance with this configuration, the power semiconductor device comprises a heat dissipating member having, adjacent the power element lead pin, a heat dissipating lead pin integrally connected to the power element lead pin and a heat dissipating portion integrally connected to the heat dissipating lead pin, which makes it possible to provide a structurally simple and inexpensive power semiconductor device that allows for increasing the heat-dissipative capabilities over the prior art and thus makes it possible to achieve an improvement in characteristics.

Moreover, in the power semiconductor device of the present invention, the lead pin configuration of the package may be a DIP-type configuration and the heat dissipating member may be arranged in an orientation that is substantially perpendicular to a top face of the package by bending a distal end of the power element lead pin toward a bottom face of the package in a direction substantially perpendicular to the top face of the package. Here, the terms “top face” and “bottom face” of the package refer to the surfaces facing, respectively, up and down when a DIP-type power semiconductor device is provided on a horizontally arranged substrate.

In this configuration, the heat dissipating member may further comprise items described in (a) and (b) below.

(a) A configuration, in which the heat dissipating member is arranged in the substantially perpendicular orientation and is bent toward a side opposite the top face of the package. This configuration is effective when there are spatial restrictions in a height direction of the package.

(b) A configuration, in which the heat dissipating member is arranged in the substantially perpendicular orientation and is bent to aside opposite a power element lead pin side end face of the package adjoining a power element lead pin exit side face of the package. This configuration is effective whenever there are spatial restrictions in the direction of the power element lead pin exit side face of the package.

Moreover, when the lead pin configuration of the package in the power semiconductor device of the present invention is a DIP-type configuration, it is preferable for the portion connecting the heat dissipating lead pin to the power element lead pin to be expanded in a height direction of the package by locating the lead pin exit position on the power element lead pin exit side face of the package away from the central position and toward the top face of the package in the height direction of the package. In this manner, the height of the lead pin can be increased while expanding the connecting portion in the height direction of the package and accordingly improving the heat-dissipative capabilities,

Moreover, in the power semiconductor device of the present invention, an external heat dissipating member provided separately from the heat dissipating member may be attached to the heat dissipating member. For example, the heat dissipating member may be configured as described in (c), (d), (e), or (f) below.

(c) A configuration, in which a through hole used for inserting a fastening member is provided in the heat dissipating portion. In this configuration, the external heat dissipating member can be securely fixed to the heat dissipating member. Moreover, a screw, etc. can be suggested as the fastening member.

(d) A configuration, in which a concave portion formed as a depression in the thickness direction is provided in the heat dissipating portion.

(e) A configuration, in which a plurality of notches of a V-shaped cross-section extending in a predetermined direction are provided in the heat dissipating portion.

The above-described configurations (d) and (e) are particularly effective when the external heat dissipating member is provided on the heat dissipating member, with a heat dissipating adhesive, a heat dissipating grease or another heat-conductive material applied therebetween.

(f) A configuration combining at least two of the above-described configurations (c) through (e).

Moreover, in the power semiconductor device of the present invention, the heat dissipating member may be folded over at a fold line extending in a predetermined direction such that the folded portions are overlapped. In this manner, a more compact heat dissipating member can be implemented. In such a case, the heat dissipating member may be provided with a portion serving as a lead pin in a position opposite the heat dissipating lead pin relative to the fold line.

Moreover, when the heat dissipating member in the power semiconductor device of the present invention is folded over at the fold line such that the folded portions are overlapped such that the folded portions are overlapped, preferably at least a portion of the heat dissipating member folded over at the fold line is used as a clipping portion possessing a clamping structure capable of clamping and holding a portion of an external heat dissipating member provided separately from the heat dissipating member. This allows for simple and ready attachment and removal of the external heat dissipating member.

Moreover, the power semiconductor device of the present invention may constitute a solid state relay comprising a light-emitting element converting electrical signals to optical signals and a light-receiving element converting the optical signals from the light-emitting element to electrical signals, with the package encapsulating the light-emitting element and light-receiving element with resin in an optically coupled relationship together with the power element. In the power semiconductor device constituting this solid state relay, the derating characteristics of the effective “on” current versus the ambient temperature can be made better by increasing its heat-dissipative capabilities, thereby allowing for an effective “on” current larger than in the prior art to flow on the high-temperature side.

The electronic device of the present invention comprises the power semiconductor device of the present invention described above.

In accordance with this configuration, the appliance comprises the power semiconductor device of the present invention, which makes it possible to provide a structurally simple and inexpensive electronic device that allows for increasing the heat-dissipative capabilities over the prior art and thus makes it possible to achieve an improvement in characteristics.

It should be noted that examples of the electronic device of the present invention include, for instance, power supply devices, household electrical appliances, inverter control devices, etc.

The lead frame member of the present invention is a lead frame member used in a power semiconductor device comprising a power element, a package encapsulating the power element with resin, a power element mounting portion used for mounting the power element, and a plurality of lead pins brought out of the package, including a power element lead pin brought out of the power element mounting portion, wherein the lead frame member comprises a heat dissipating member having, adjacent the power element lead pin, a heat dissipating lead pin integrally connected to the power element lead pin and a heat dissipating portion integrally connected to the heat dissipating lead pin.

In accordance with this configuration, the member comprises a heat dissipating member having, adjacent the power element lead pin, a heat dissipating lead pin integrally connected thereto and a heat dissipating portion integrally connected to the heat dissipating lead pin, thereby making it possible to obtain the power semiconductor device of the present invention. Accordingly, a structurally simple and inexpensive power semiconductor device can be obtained that allows for increasing the heat-dissipative capabilities over the prior art and thus makes it possible to achieve an improvement in characteristics.

The method of making a power semiconductor device of the present invention is a method of making a DIP-type power semiconductor device comprising a power element, a package encapsulating the power element with resin, a power element mounting portion used for mounting the power element, and a plurality of lead pins brought out of the package, including a power element lead pin brought out of the power element mounting portion. The method comprises the steps of lead frame member preparation, which involves preparing a primary lead frame member and a secondary lead frame member used for mounting the power element, wherein a lead frame member comprising a heat dissipating member having, adjacent the power element lead pin, a heat dissipating lead pin integrally connected to the power element lead pin and a heat dissipating portion integrally connected to the heat dissipating lead pin is prepared as the secondary lead frame member; lead frame member placement, which involves mounting the power element on the secondary lead frame member and arranging the primary and secondary lead frame members in an opposed relationship; package molding, which involves molding the package by encapsulating the power element with resin; and lead frame member finishing, which involves bending a distal end of the power element lead pin toward a bottom face of the package in a direction substantially perpendicular to a top face of the package such that the heat dissipating member is arranged in an orientation that is substantially perpendicular to the top face.

In accordance with this configuration, the lead frame member of the present invention is prepared in the lead frame member preparation step, which makes it possible to obtain the power semiconductor device of the present invention. Accordingly, a structurally simple and inexpensive power semiconductor device can be obtained that allows for increasing the heat-dissipative capabilities over the prior art and thus makes it possible to achieve an improvement in characteristics.

Moreover, in the method of making a power semiconductor device of the present invention, a lead frame member provided with a slot and having the heat dissipating portion of the heat dissipating member integrally connected in portions adjacent to the slot may be prepared as the secondary lead frame member in the lead frame member preparation step, and a cutting step involving cutting the portions adjacent to the slot may be further included subsequent to the package molding step and prior to the lead frame member finishing step.

### BRIEF DESCRIPTION OF THE DRAWINGS

FIG. 1a is a schematic see-through view, shown as viewed from the side, of a solid state relay used in an embodiment of the power semiconductor device of the present invention.

FIG. 1b is a schematic see-through view of the solid state relay shown in FIG. 1a, as viewed in plan view.

FIG. 2 is a graph illustrating the derating characteristics of the effective “on” current vs. ambient temperature in the solid state relay shown FIG. 1a, as compared with the derating characteristics in a conventional solid state relay.

FIG. 3 is a schematic plan view illustrating an alternate embodiment of the heat dissipating member of the solid state relay shown in FIG. 1a.

FIG. 4 is a schematic plan view illustrating another alternate embodiment of the heat dissipating member of the solid state relay shown in FIG. 1a.

FIG. 5a, which illustrates yet another alternate embodiment of the heat dissipating member of the solid state relay shown in FIG. 1a, is a schematic side view of the heat dissipating member portion showing a state prior to the folding of the heat dissipating member.

FIG. 5b is a schematic plan view showing a state produced after folding over the heat dissipating member of the solid state relay shown in FIG. 6a.

FIG. 6 is a schematic side view illustrating an example, in which the heat dissipating member of the solid state relay shown in FIG. 1a is provided with a portion serving as a lead pin in a location opposite the heat dissipating lead pin relative to the fold line.

FIG. 7a, which illustrates yet another alternate embodiment of the heat dissipating member of the solid state relay shown in FIG. 1a, shows an example of a through hole provided in the heat dissipating portion of the heat dissipating member.

FIG. 7b is a schematic plan view showing a state produced by folding the heat dissipating portion shown in FIG. 7a over along the fold line aligned with the width direction of the heat dissipating portion.

FIG. 8 is a schematic plan view showing a state, in which a fastening member is used to attach an external heat dissipating member to the heat dissipating portion in the solid state relay shown in FIG. 7a.

FIG. 9a, which illustrates yet another alternate embodiment of the heat dissipating member of the solid state relay shown in FIG. 1a, shows an example of notches provided in the heat dissipating portion of the heat dissipating member.

FIG. 9a, which illustrates yet another alternate embodiment of the heat dissipating member of the solid state relay shown in FIG. 1a, shows an example of a concave portion provided in the heat dissipating portion.

FIG. 10 is a schematic plan view illustrating an example of a clipping portion possessing a clamping structure, formed in the heat dissipating member of the solid state relay shown in FIG. 1a.

FIG. 11 is a schematic side view illustrating an example of a connecting portion expanded in a height direction of the package in the heat dissipating member of the solid state relay shown in FIG. 1a.

FIG. 12a, which shows a solid state relay in a fabrication process subsequent to the lead frame member preparation step and lead frame member placement step in the process of making the solid state relay illustrated in FIG. 1a, is a schematic see-through view of the solid state relay in the process of fabrication as viewed in plan view.

FIG. 12b is a schematic see-through view, shown as viewed from the side, of the solid state relay illustrated in FIG. 12a.

FIG. 13a is a schematic plan view showing a solid state relay in a process of fabrication, comprising an exemplary secondary lead frame member, in which the heat dissipating portion of the heat dissipating member is integrally connected in portions adjacent to the slot.

FIG. 13b is a cross-sectional view taken along line C-C in FIG. 13a.

FIG. 14a, which illustrates an exemplary internal structure of a conventional DIP-type solid state relay, is a schematic see-through view of the solid state relay as viewed from the side.

FIG. 14b is a schematic see-through view of the solid state relay shown in FIG. 14a, as viewed in plan view.

FIG. 15a is a schematic plan view of a solid state relay illustrating an example of heat dissipating pins provided on the outer surface of a conventional DIP-type solid state relay.

FIG. 15b is a schematic side view of the solid state relay shown in FIG. 15a.

FIG. 16 is a graph showing the derating characteristics of the effective “on” current vs. ambient temperature in a conventional solid state relay.

### DESCRIPTION OF THE PREFERRED EMBODIMENTS

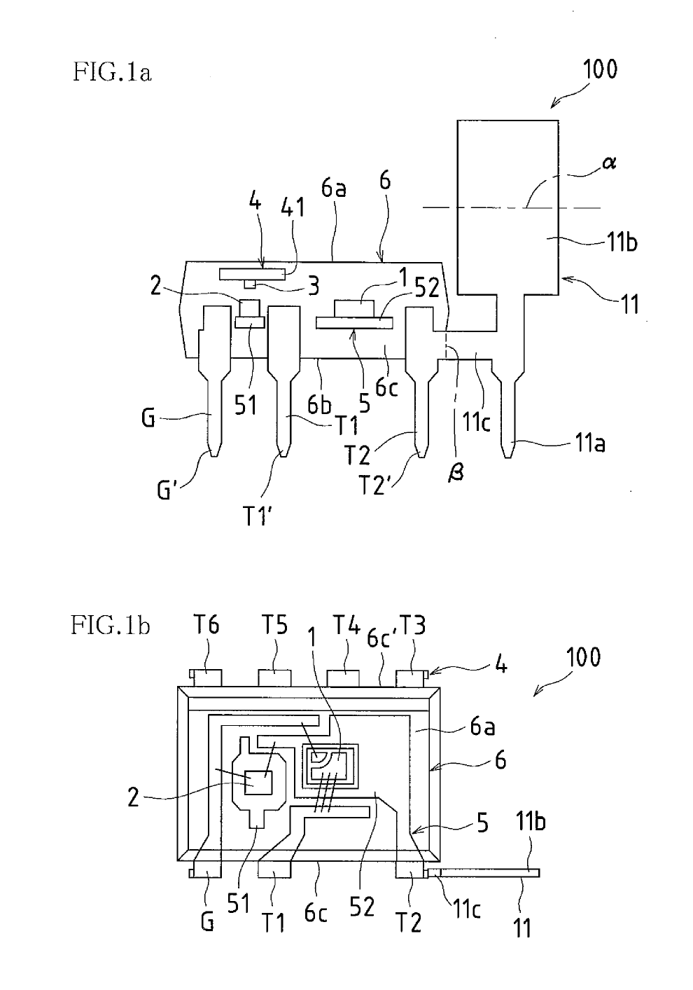

Below, the embodiments of the present invention are explained in detail by referring to the attached drawings. FIGS. 1a and 1b are diagrams illustrating a solid state relay representing an embodiment of the power semiconductor device of the present invention, with FIG. 1a being a schematic see-through view of the solid state relay as viewed from the side, and FIG. 1b being a schematic see-through view of the solid state relay as viewed in plan view.

The solid-state relay 100 illustrated in FIGS. 1a and 1b comprises a power element 1, a light-emitting element 3 converting electrical signals into optical signals, a light-receiving element 2 converting optical signals from the light-emitting element 3 into electrical signals, a package 6, in which the light-emitting element 3 and light-receiving element 2 are encapsulated with resin in an optically coupled relationship together with the power element 1, a power element mounting portion 52 used for mounting the power element 1, and a plurality of lead pins G, T1-6 brought out of the package 6. Note that it is assumed that one of these lead pins G, T1-6 is a power element lead pin T2, which is brought out of the power element mounting portion 52.

More specifically, the power element 1 is assumed to be a power control semiconductor element chip 1, such as a triac element chip, thyristor element chip, etc. It is assumed that the light-emitting element 3 is a light-emitting diode chip or another light-emitting element chip 3. Moreover, it is assumed that the light-receiving element 2 is a phototriac chip or another light-receiving element chip 2 receiving optical signals from the light-emitting element chip 3 and converting them to electrical signals.

Moreover, the solid state relay 100 comprises a primary lead frame 4 and a secondary lead frame 5, which are arranged in a mutually opposed relationship.

The primary lead frame 4 comprises a mounting piece 41, which is an example of a element mounting portion, with the light-emitting element chip 3 mounted on the element mounting portion 41. The secondary lead frame 5 comprises mounting pieces 51, 52, which represent examples of multiple element mounting portions arranged in substantially the same plane, with the light-receiving element chip 2 and power control semiconductor element chip 1 mounted, respectively, on the element mounting portions 51 and 52. Moreover, the element chips 1, 2, and 3 and the corresponding lead frames are electrically connected via wires.

In addition, the secondary lead frame 5 comprises a heat dissipating member 11 having a heat dissipating lead pin 11a provided separately from the lead pins G, T1-6 brought out of the package 6 and a heat dissipating portion (here, a plate-shaped heat dissipating portion) 11b formed integrally with the heat dissipating lead pin 11a. The heat dissipating lead pin 11a, which is adjacent the power element lead pin T2 brought out of the power element mounting portion 52 used for the mounting power control semiconductor element chip 1, is integrally connected to the power element lead pin T2. The heat dissipating lead pin 11a is provided with a connecting portion lie used for connection to the power element lead pin T2. The heat dissipating portion 11b is arranged in the vicinity of the package 6.

Since the solid state relay 100 illustrated in FIGS. 1a and 1b only has a heat dissipating member 11 connected via a lead connection to (formed integrally with) the power element lead pin T2 in the solid state relay main body, it is structurally simple and inexpensive. Furthermore, since the two leads, i.e. the heat dissipating lead pin 11a of the heat dissipating member 11 and the power element lead pin T2 of the solid state relay main body, are integrally formed, the heat-dissipative area is expanded in comparison with conventional solid state relays to an extent corresponding to the heat dissipating member 11, thereby allowing for an improvement in the efficiency of heat dissipation from the power element lead pin T2. As a result, the heat-dissipative capabilities of the solid state relay as a whole can be improved, the heat-dissipative effects of the solid state relay 100 obtained upon substrate mounting, not shown, can be correspondingly increased in comparison with prior-art, thereby making it possible to decrease the thermal resistance of the solid state relay main body.

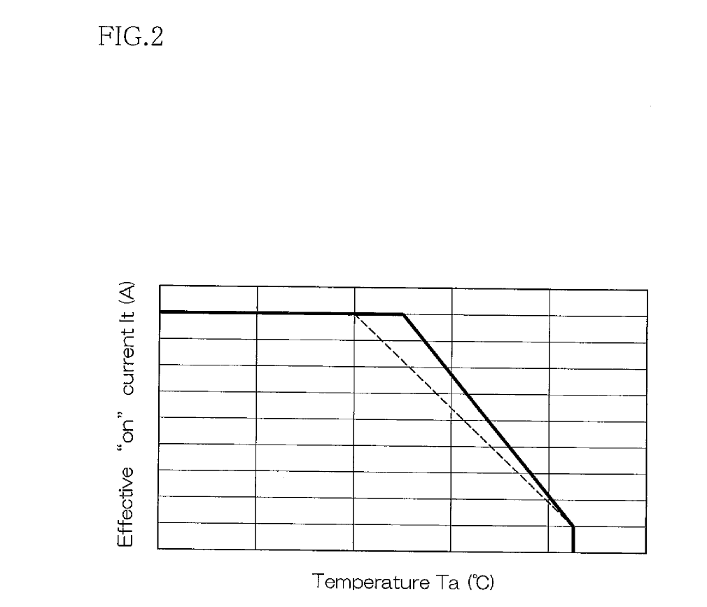

Accordingly, the effective “on” current, which in the past exhibited the derating characteristics described by the dashed line in FIG. 2, now exhibits the derating characteristics indicated by the solid line in the same figure and a high effective “on” current can be passed even on the high-temperature side.

To illustrate the solid state relay 100 more specifically, the lead pin configuration of the package 60 is assumed to be of the DIP type. In other words, the package 6 is assumed to be of a substantially hexahedral shape having rectangular lead pin exit side faces 6c, 6c′ on two sides thereof, from which metal lead pins are brought out.

The power control semiconductor element chip 1 in the secondary lead frame 5 of the solid state relay 100 is connected to the pin T2 located at the end-most position aligned with one of the lead pin exit side faces, 6c, of the package 6.

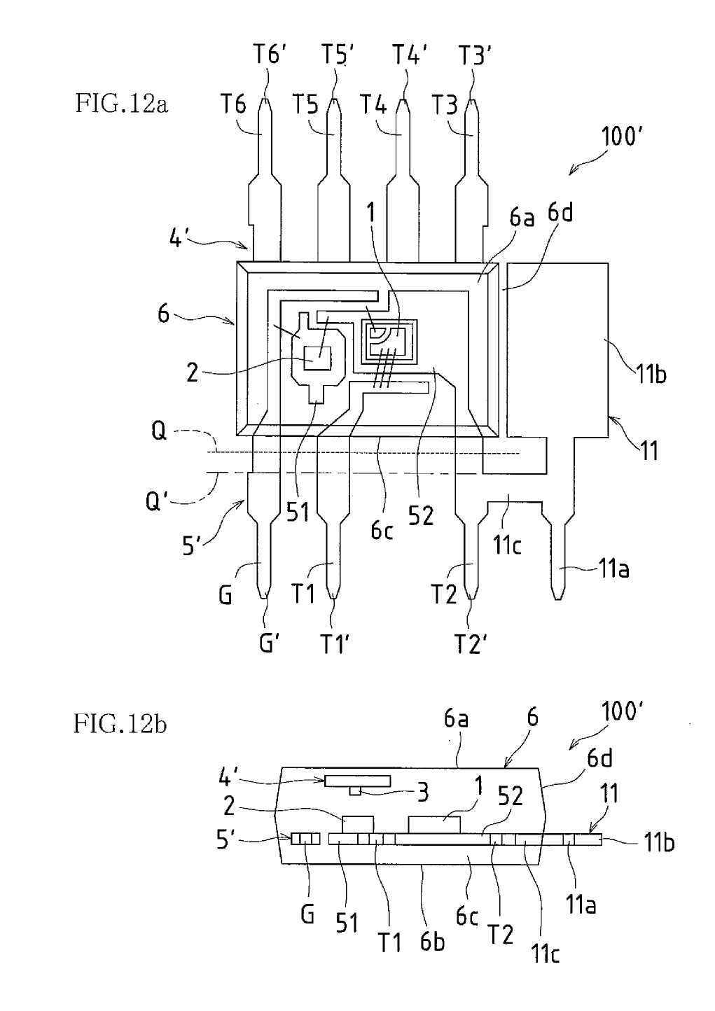

On the lead pin exit side face 6c, the distal ends G′, T1′, and T2′ of the lead pins G, T1, T2, which include the power element lead pin T2, are bent toward the bottom face 6b of the package 6 such that they are substantially perpendicular to the top face 6a of the package 6. In this manner, following the bending of the power element lead pin T2, the heat dissipating member 11 is arranged in an orientation that is substantially perpendicular to the top face 6a. As a result, when the solid state relay 100 is attached to a substrate directly or indirectly via an attachment member such as a socket, etc., the heat dissipating member 11 is kept on the substrate or the attachment member by the heat dissipating lead pin 11a and power element lead pin T2, strengthening the connection between the heat dissipating lead pin 11a and power element lead pin T2. It should be noted that the locations, at which the lead pins G, T1, and T2 are bent, are assumed to be anywhere on the package 6 side relative to an imaginary straight line Q′ (see the dashed line in FIG. 12a, which is explained below), which is aligned with the lead pin exit side face 6c and passes through the end position of the connecting portion 11c next to the package 6.

An ordinary inter-lead pitch (e.g., a 2.54-mm pitch or a 1.27-mm pitch) can be used as the inter-lead pitch between the heat dissipating lead pin 11a and power element lead pin T2. This allows for mounting on various general-purpose substrates. Moreover, the invention is not limited thereto and can be used with special-purpose substrates.

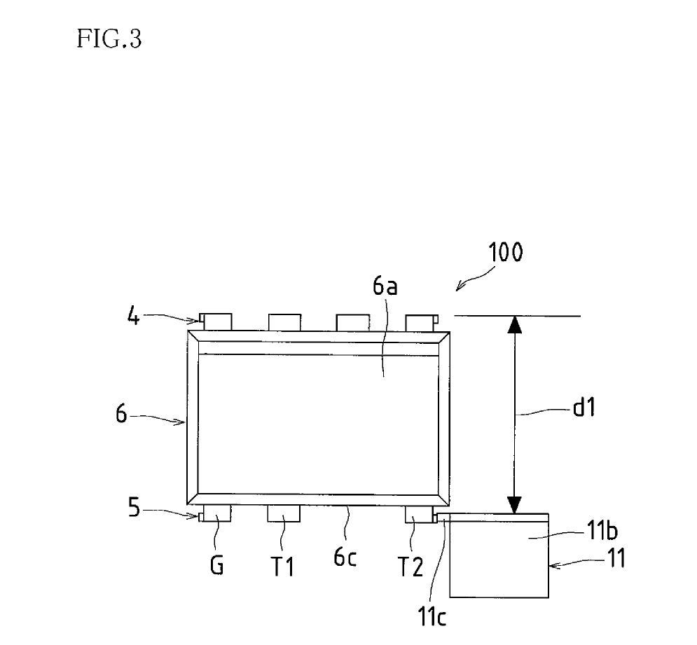

FIG. 3 is a schematic plan view illustrating an alternate embodiment of the heat dissipating member 11 in the solid state relay 100 shown in FIG. 1a.

When there are spatial restrictions in a height direction of the package 6 during placement of the solid state relay 100, the heat dissipating member 11, after being arranged in the substantially perpendicular orientation, can be folded (e.g. folded at substantially right angles) at a fold line (see the dashed line “α” in FIG. 1a) aligned with the width direction of the heat dissipating member 11. In this manner, space in the height direction can be ensured. However, since the solid state relay 100 requires a predetermined insulating distance to be provided between the primary lead frame 4 and secondary lead frame 5, in terms of ensuring the distance d1 between the primary lead frame 4 and secondary lead frame 5, it is preferable for the heat dissipating member 11 to be arranged in the substantially perpendicular orientation and then, as shown in FIG. 3, bent to the side opposite the top face 6a of the package 6 relative to a power element lead pin exit side face 6c of the package 6.

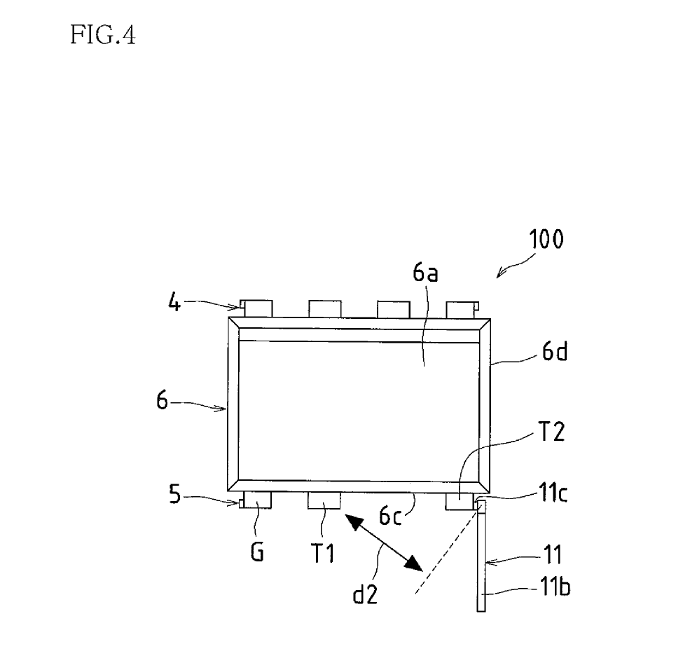

FIG. 4 is a schematic plan view illustrating another alternate embodiment of the heat dissipating member 11 of the solid state relay 100 shown in FIG. 1a.

When there are spatial restrictions in the direction of the power element lead pin exit side face 6c of the package 6 (in this case, in the longitudinal direction of the package 6) during placement of the solid state relay 100, the heat dissipating member 11, after being arranged in the substantially perpendicular orientation, can be folded at a fold line (see the dashed line “B” in FIG. 1a) aligned with the package height direction of the heat dissipating member 11 (in this case, connecting portion 11c). At such time, from the standpoint of ensuring the insulating distance between the primary lead frame 4 and secondary lead frame 5, the heat dissipating member 11, after being arranged in the substantially perpendicular orientation as shown in FIG. 4, is preferably bent to a side opposite a power element lead pin side end face 6d aligned with the transverse direction of the package 6, which adjoins the side face 6c, relative to the power element lead pin exit side face 6c of the package 6.

It should be noted that since in such a case the spacing between the power element lead pin T2, to which the heat dissipating member 11 is connected, and the lead pin T1, which is located in the vicinity of the side opposite the heat dissipating lead pin 11a of the power element lead pin T2, is determined in accordance with the “Electrical Appliance and Material Safety Law” and other laws and regulations, care should be taken to ensure that the spacing d2 between the lead pin T2 and lead pin T1 is not narrowed down by the folded heat dissipating member 11.

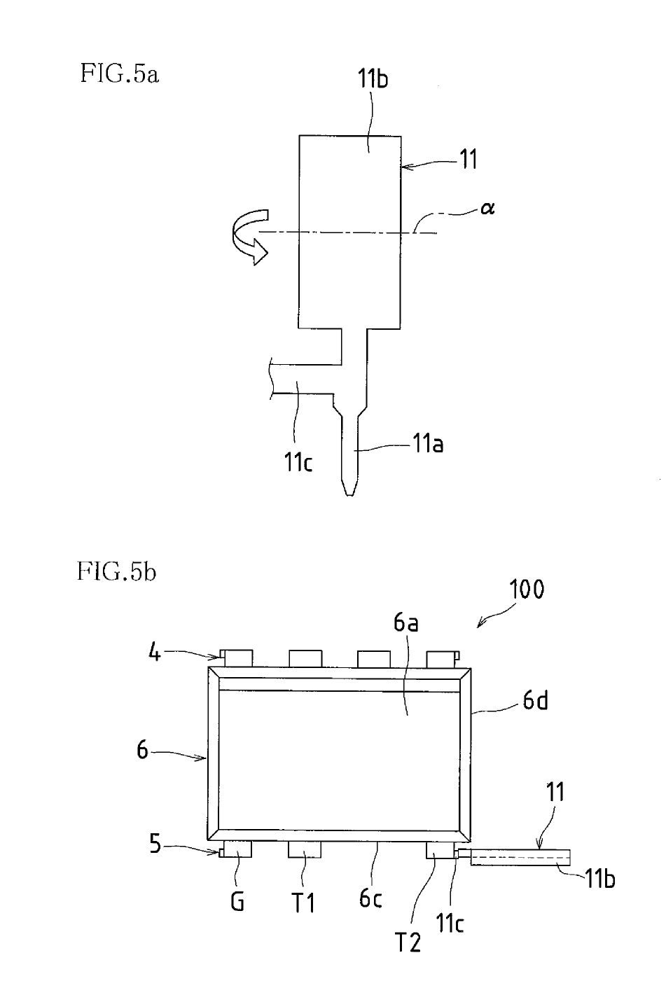

When there are spatial limitations both in the height direction and width direction of the package 6, or when there are spatial limitations both in the longitudinal direction and width direction of the package 6, as shown in FIGS. 5a and 5b, the heat dissipating member 11 is preferably folded over at a fold line extending in a predetermined direction (in the example of FIG. 5a, at the fold line “α” extending in the width direction of the heat dissipating member 11) such that the folded portions are overlapped.

FIGS. 5a and 5b illustrate additional alternate embodiments of the heat dissipating member 11 of the solid state relay 100 shown in FIG. 1a, with FIG. 5a being a schematic side view of the heat dissipating member portion showing a state prior to folding over the heat dissipating member 11, and FIG. 5b being a schematic plan view showing a state produced after folding the heat dissipating member 11.

Folding over the heat dissipating member 11 at the fold line extending in a predetermined direction (in the example shown, fold line “α”) such that the folded portions are overlapped as shown in FIG. 5a makes it possible to achieve greater compactness, as shown in FIG. 5b.

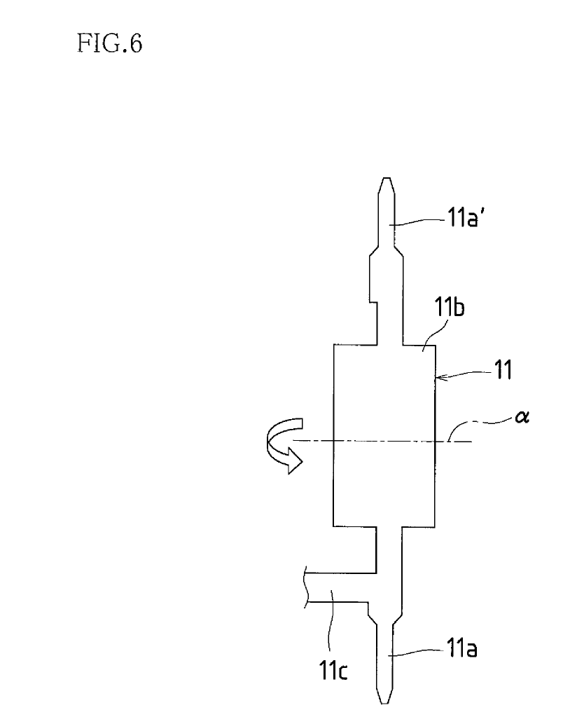

Moreover, as shown in FIG. 6, the heat dissipating member 11 is preferably provided with a portion 11a′ serving as a lead pin in a location opposite the heat dissipating lead pin 11a relative to the fold line “α”.

FIG. 6 is a schematic side view illustrating an example, in which the heat dissipating member 11 of the solid state relay 100 shown in FIG. 1a is provided with a portion 11a′ serving as a lead pin in a location opposite the heat dissipating lead pin 11a relative to the fold line.

Imparting a lead-like shape to the side opposite the heat dissipating lead pin 11a across the fold line “α” in the heat dissipating member 11 permits stable insertion of the lead pins in their overlapped state into a substrate or into an attachment member. Here, the portions of the heat dissipating member 11 that are overlapped at the fold line “α” are shaped symmetrically relative to the fold line.

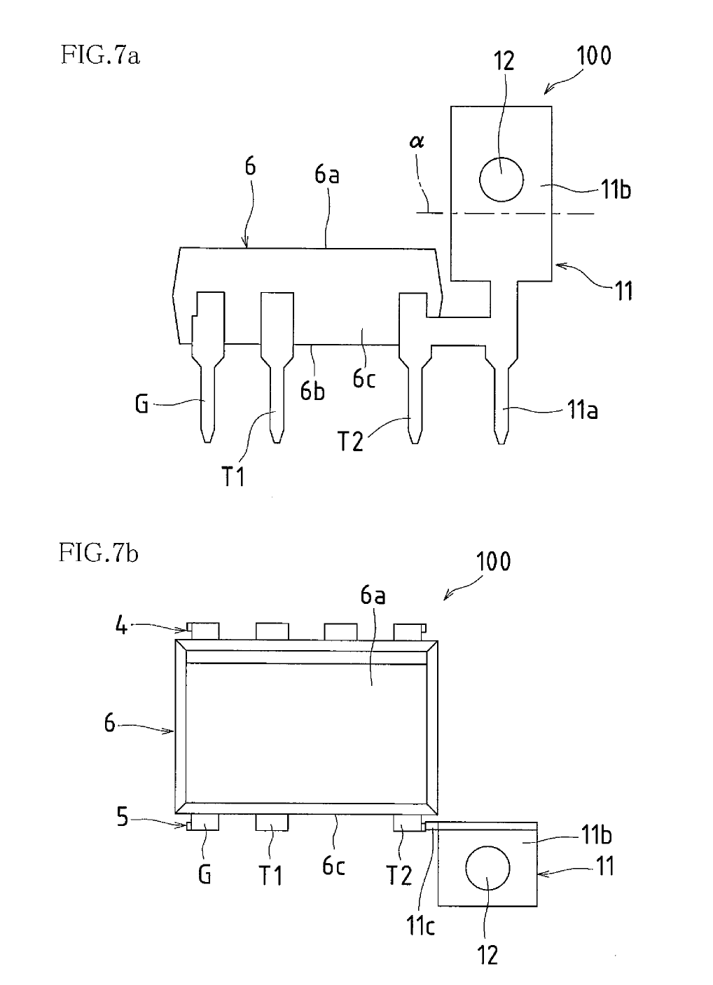

Incidentally, depending on the intended purpose of use of the solid state relay 100 shown in FIG. 1a, in some cases the heat dissipating effects may be insufficient with only the heat dissipating member 11. In such cases, a through-hole 12, which is used for inserting a fastening member 13, such as a screw or rivet, is preferably provided in the heat dissipating portion 11b, as shown in FIGS. 7a and 7b.

FIGS. 7a and 7b illustrate yet another alternate embodiment of the heat dissipating member 11 used in the solid state relay 100 shown in FIG. 1a, with FIG. 7a illustrating an example of a through-hole 12 provided in the heat dissipating portion 11b of the heat dissipating member 11, and FIG. 7b showing a state obtained by folding the heat dissipating portion 11b shown in FIG. 7a at the fold line “α” aligned with the width direction of the heat dissipating portion 11b.

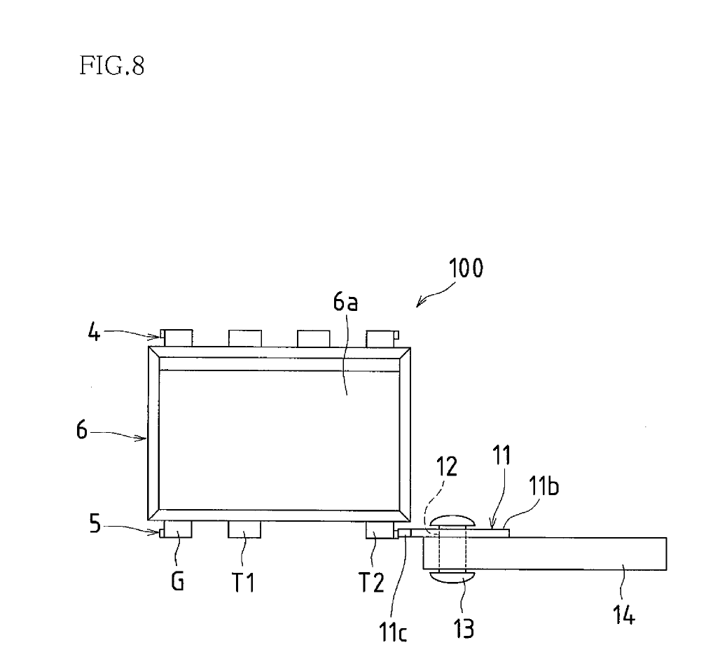

As shown in FIG. 8, in order to increase the heat-dissipative capabilities, an external heat dissipating member (here, an external heat dissipating plate) provided independently of the heat dissipating member 11 can be secured in the through hole 12 provided in the heat dissipating portion 11b using the fastening member 13.

FIG. 8 is a schematic plan view showing a state, in which the fastening member 13 is used to attach an external heat dissipating member 14 to the heat dissipating portion 11b in the solid state relay 100 shown in FIG. 7a.

Due to its better thermal capacity for heat release, it is desirable for the fastening member 13 to be made from metal. The material of the fastening member 13 is not, however, limited to metal, and, with account taken of its electrical insulating properties, the member can be formed from resin and other insulating materials.

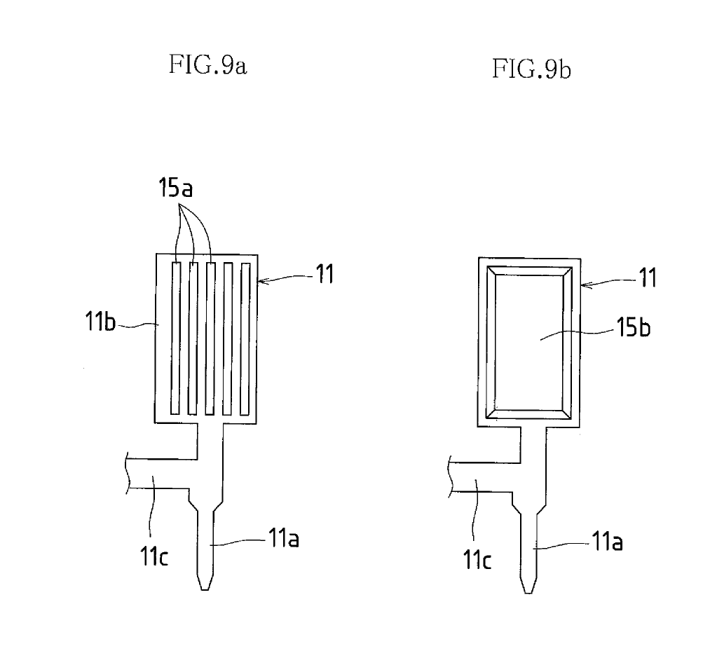

Heat conduction between the heat dissipating member 11 and external heat dissipating member 14 can be enhanced using a heat-conductive material, such as a heat dissipating adhesive, a heat dissipating grease, etc. In such a case, as shown in FIG. 9a, a plurality of notches (grooves) 15a of a V-shaped cross-section extending in a predetermined direction, or, as shown in FIG. 9b, a concave portion 11b formed as a depression in the thickness direction may be provided in the heat dissipating portion 11b.

FIGS. 9a and 9b illustrate yet another alternate embodiment of the heat dissipating member 11 used in the solid state relay 100 shown in FIG. 1a, with FIG. 9a illustrating an example of notches 16a provided in the heat dissipating portion 11b of the heat dissipating member 11, and FIG. 9b illustrating an example of a concave portion 15b provided in the heat dissipating portion 11b.

As shown in FIGS. 9a and 9b, the heat dissipating portion 11b is provided with notches 15a of a V-shaped cross-section or a concave portion 15b, thereby ensuring the thickness of the adhesive agent or another heat-conductive adhesive material connecting it to the external heat dissipating member 14 and increasing the bonding strength. Furthermore, excess adhesive, or another heat-conductive material used, can be allowed to escape when there is a through-hole 12 provided in the heat dissipating portion 11b, as shown in FIGS. 7a and 7b, and a screw etc. is used for fastening.

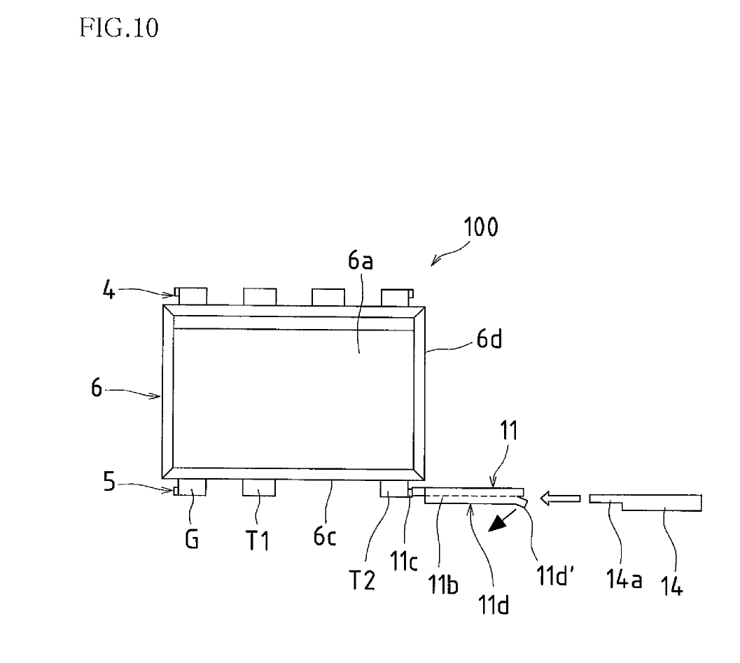

Moreover, when the heat dissipating member 11 is folded over at the fold line “α” such that the folded portions are overlapped, as shown in FIG. 5a, FIG. 5b, and FIG. 6, the folded and overlapped portion is preferably used as a clipping portion lid possessing a clamping structure capable of clamping and holding a portion 14a of the external heat dissipating member 14, as shown in FIG. 10.

FIG. 10 is a schematic plan view illustrating an example of a clipping portion 11d possessing a clamping structure, formed in the heat dissipating member 11 of the solid state relay 100 shown in FIG. 1a.

The heat dissipating member 11 may be provided with a gap in the folded-over portion so as permit a portion 14a of the independent external heat dissipating member 14 to be inserted and secured therein. In this manner, the connection (attachment/detachment) of the external heat dissipating member 14 is facilitated.

Moreover, if a clipping portion lid is formed in the heat dissipating member 11, the external heat dissipating member 14 may be firmly secured to the heat dissipating member 11 using a fastening member if a through-hole 12 is provided in the heat dissipating member 11, as described above, for the purpose of inserting a screw or another fastening member.

Moreover, at the insertion end of the external heat dissipating member 14, the heat dissipating member 11 is preferably provided with a folding guide portion 11d′ for guiding the portion 14a of the external heat dissipating member 14 into the correct position. In this manner, stress on elements during attachment of the external heat dissipating member 14 can be alleviated.

Thus, further improvement of heat-dissipative capabilities can be achieved by additionally providing the heat dissipating member 11 with an external heat dissipating member 14.

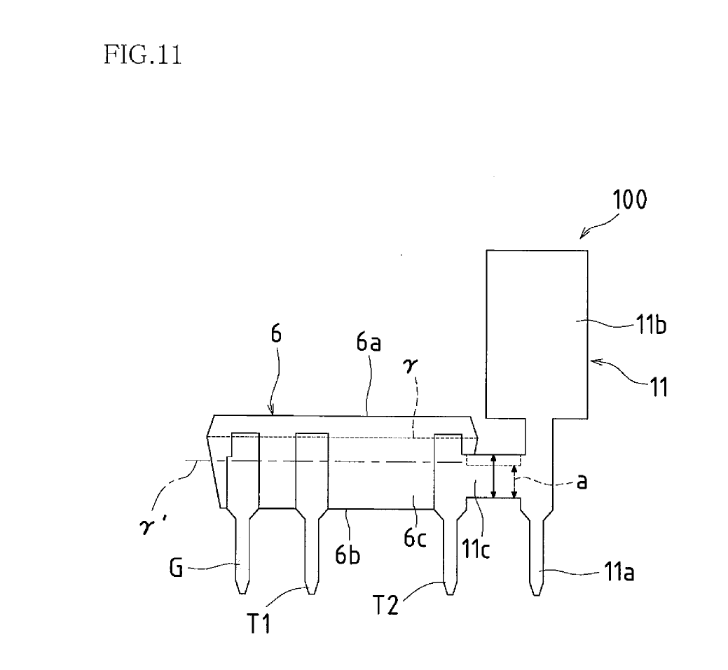

On the other hand, in addition to attaching the external heat dissipating member 14, or when there is no need to attach the external heat dissipating member 14, instead of that, as shown in FIG. 11, the positions, at which the lead pins G, T1, and T2 exit from the power element lead pin exit side face 6c of the package 6 (see the dashed line y in the figure) are preferably located away from the central position (see the dashed line γ′) and closer to the top face 6a of the package 6 in the height direction of the package 6, thereby expanding the connecting portion 11c between the heat dissipating lead pin 11a and power element lead pin T2 in the height direction of the package 6.

FIG. 11 is a schematic side view illustrating an example of a connecting portion lie expanded in the height direction of the package 6 in the heat dissipating member 11 of the solid state relay 100 shown in FIG. 1a.

The lead pin exit positions on the package 6 can located, for instance, at the parting position (parting line γ) of the top and bottom portions of the mold used for package molding.

Shifting the parting line γ of the package 6 in the direction of the top face 6a of the package 6 can increase the distance from the top face of the attachment member or lead pin substrate to the parting line “γ”, thereby making it possible to increase the length of the lead pins brought out of the package 6. For this reason, the surface area of the lead pins can be increased and the connecting portion 11c between the heat dissipating lead pin 11a and power element lead pin T2 can be made larger as well. This makes it possible to achieve an improvement in terms of heat-dissipative capabilities. It should be noted that the symbol “a” in FIG. 11 indicates the width of the connecting portion 11c illustrated in FIG. 1a in the height direction.

The solid state relay 100 explained above can be utilized in electronic devices such as power-supply devices, household appliances, inverter control devices, etc.

Next, explanations will be provided regarding the method of making the DIP-type power semiconductor device of the present embodiment and lead frame member of the present embodiment. Here, explanations will be provided using fabrication of the solid state relay 100 illustrated in FIG. 1a as an example.

FIGS. 12a and 12b show a solid state relay 100′ in a fabrication step subsequent to the lead frame member preparation step and lead frame member placement step in the process of making the solid state relay 100 illustrated in FIG. 1a, with FIG. 12a being a schematic see-through view of the solid state relay 100′ in the process of fabrication, shown as viewed in plan view, and FIG. 12b being a schematic see-through view of the solid state relay 100′ in the process of fabrication, shown as viewed from the side.

[Lead Frame Member Preparation]

The primary lead frame member 4′ and secondary lead frame member 5′ prepared in this embodiment are manufactured prior to the fabrication of the solid state relay 100 illustrated in FIG. 1a. It should be noted that the lead frame members used in the process of fabrication of the solid state relay 100 are also represented using symbols 4′ and 5′.

The lead frame member preparation step involves preparing the primary lead frame member 4′, on which the light-emitting element chip 3 is mounted, and a secondary lead frame member 5′, on which the light-receiving element chip 2 and power control semiconductor element chip 1 are mounted. It should be noted that the primary and secondary lead frame members 4′ and 5′ are assumed to be shaped so as to be aligned in substantially the same plane.

The secondary lead frame 5′ is a lead frame member comprising a heat dissipating member 11 having a heat dissipating lead pin 11a provided separately from the lead pins G, T1-6 brought out of the package 6 and a heat dissipating portion (here, a plate-shaped heat dissipating portion) 11b integrally connected to the heat dissipating lead pin 11a. In this lead frame member, the heat dissipating lead pin 11a, which is adjacent the power element lead pin T2 brought out of the power element mounting portion 52 used for the mounting power control semiconductor element chip 1, is integrally connected to the power element lead pin T2.

[Lead Frame Member Placement]

Next, the light-emitting element chip 3 is mounted on the primary lead frame member 4′, and the light-receiving element chip 2 and power control semiconductor element chip 1 are mounted on the secondary lead frame member 5′. The primary and secondary lead frame members 4′ and 5′ are arranged in an opposed relationship such that the light-emitting element 3 and light-receiving element 2 are optically coupled. At such time, the primary and secondary lead frame members 4′ and 5′ are substantially parallel to the top face 6a and bottom face 6b of the molded package 6.

[Package Molding]

Subsequently, the package 6 is molded by encapsulating the light-emitting element chip 3, light-receiving element chip 2 and power control semiconductor element chip 1 with resin. Upon completion of the resin encapsulation, resin burrs are removed from the package 6 and individual leads are separated from the primary and secondary lead frame members 4′ and 5′, thereby forming lead pins. At such time, the connecting portion 11c between the power element lead pin T2 and heat dissipating member 11 is not cut and left intact.

[Lead Frame Member Finishing]

In the primary lead frame member 4′, to which heat dissipating member 11 is not connected, the distal ends T3′-T6′ of the lead pins T3-T6 are bent toward the bottom face 6b of the package 6 such that the distal ends T3′-T6′ are rendered substantially perpendicular to the top face 6a of the package 6.

On the other hand, in the secondary lead frame member 5′, which has the heat dissipating member 11 connected thereto, the distal ends G′, T1′, T2′ of the lead pins G, T1, and T2, which include the power element lead pin T2, are bent at fold line Q (see the dashed line in FIG. 12a), which is aligned with the power element lead pin exit side face 6c, to the bottom face 6b of the package 6 in a direction substantially perpendicular to the top face 6a of the package 6 such that the heat dissipating member 11 is arranged in an orientation substantially perpendicular to the top face 6a of the package 6. It should be noted that the locations, at which the lead pins G, T1, and T2 are bent, are assumed to be anywhere toward the package 6 side relative to an imaginary straight line Q′ (see the dashed line in FIG. 12a), which is aligned with the lead pin exit side face 6c and passes through the end position of the connecting portion 11c next to the package 6.

As a result, when the lead pins G, T1, and T2 are bent, bending takes place at the fold line Q of the lead pins G, T1, and T2 located toward the package 6 side relative to the imaginary straight line Q′, such that the orientation of the heat dissipating member 11, which is connected to the lead pin T2, is changed in the direction of bending following the bending of the lead pin T2 from an orientation substantially parallel to the top face 6a of the package to a direction perpendicular to the top face 6a of the package 6 (see FIGS. 1a and 1b).

In the method of making a DIP-type power semiconductor according to the present embodiment, after bending the lead pins G, T1, and T2 in the lead frame member finishing step, the heat dissipating member 11 may be bent to the side opposite the top face 6a of the package 6. In such a case, the solid state relay 100 shown in FIG. 3 can be obtained.

Moreover, after bending the lead pins G, T1, and T2 in the lead frame member finishing step, the heat dissipating member 11 may be further bent to the side opposite the power element lead pin side end face 6d in the transverse direction of the package 6, which adjoins the power element lead pin exit side face 6c of the package 6. In such a case, the solid state relay 100 shown in FIG. 4 can be obtained.

Moreover, after bending the lead pins G, T1, and T2 in the lead frame member finishing step, the heat dissipating member 11 may be further folded over at a fold line extending in a predetermined direction (e.g. the fold line “α” shown in FIG. 5a) such that the folded portions are overlapped. In such a case, the solid state relay 100 shown in FIG. 5b can be obtained.

Incidentally, the resin burrs formed between the package 6 and heat dissipating portion 11b during resin encapsulation in the package molding step have to subjected to burr removal using a mold etc. This may result in the deformation of the heat dissipating portion 11b during burr removal.

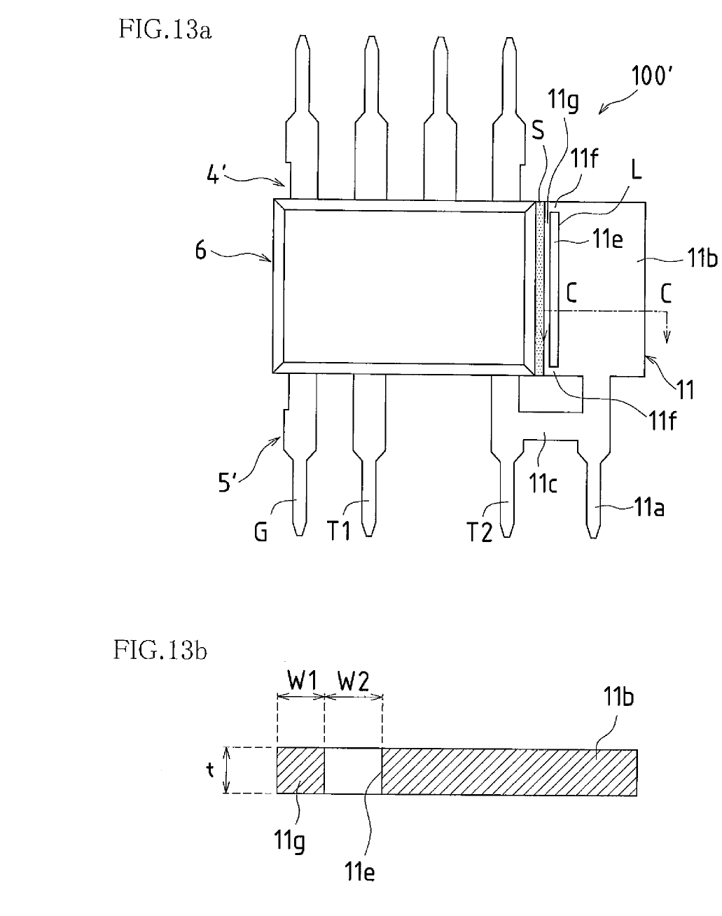

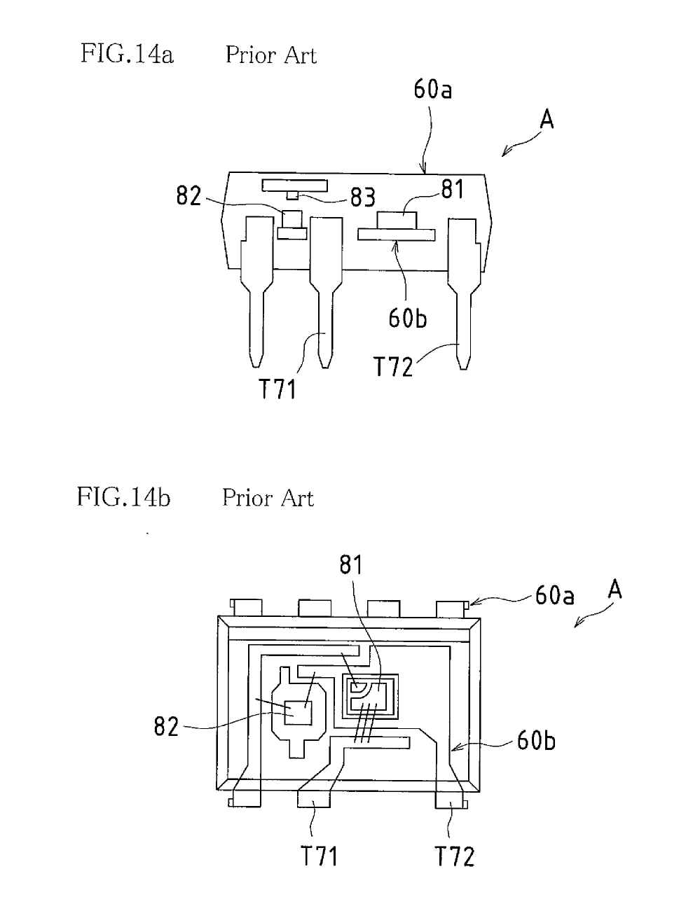

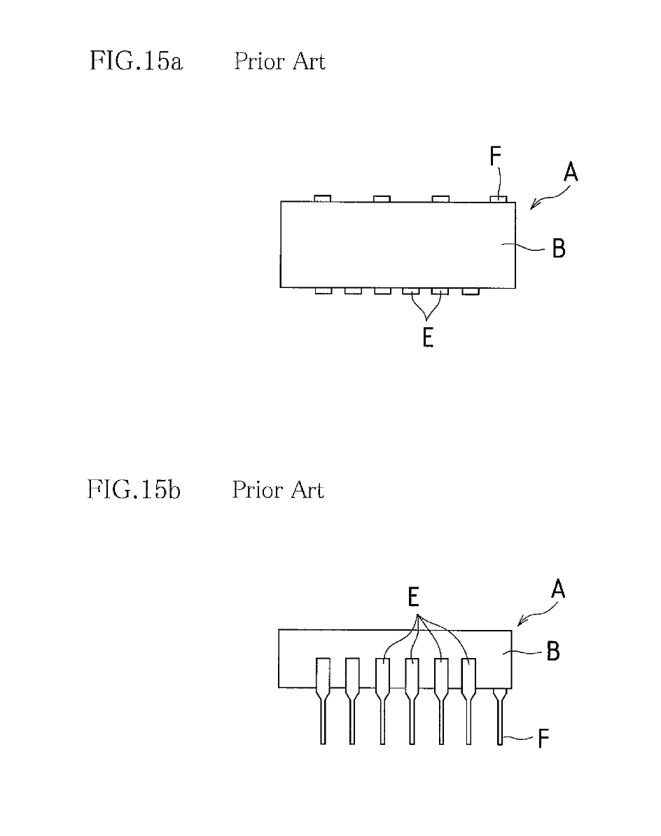

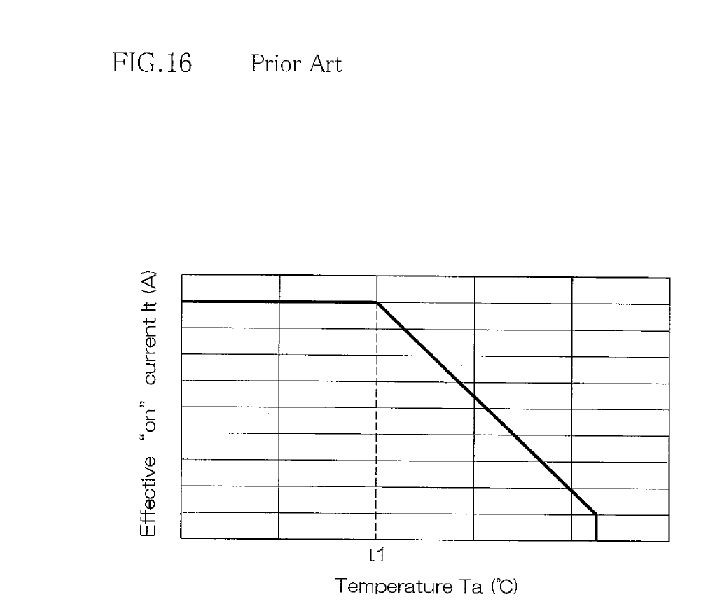

Accordingly, in the method of making a DIP-type power semiconductor device of the present embodiment, as shown in FIG. 13a, a lead frame member provided with a slot lie and having the heat dissipating portion 11b of the heat dissipating member 11 integrally connected in the portions 11f adjacent to the slot 11e is preferably prepared as the secondary lead frame member 5′ in the lead frame member preparation step, and a cutting step involving cutting the portions 11f adjacent to the slot lie is preferably further included subsequent to the package molding step and prior to the lead frame member finishing step.

FIG. 13a is a schematic plan view showing a solid state relay 100′ in the process of fabrication, comprising an exemplary secondary lead frame member 5′, in which the heat dissipating portion 11b of the heat dissipating member 11 is integrally connected in the portions 11f adjacent to the slot lie. In addition, FIG. 13b is a cross-sectional view taken along line C-C in FIG. 13a.

Namely, in the secondary lead frame member 5′ the slot 11e is provided along the edge L of the heat dissipating portion 11b next to the package 6 in such a manner that it is interposed between a resin burr S and heat dissipating portion 11b for the purpose of preventing the deformation of the heat dissipating portion 11b during the removal of the resin burr S formed between the package 6 and heat dissipating portion 11b. The heat dissipating portion 11b and the removed portion 11g, which is removed together with the resin burr S, are integrally connected in the portions 11f adjacent to the slot 11e, i.e. the two end portions 11f along the edge L of the heat dissipating portion 11b. Moreover, the width W1 of the removed portion 11g is set to a length equal to or greater than the plate thickness t of the secondary lead frame member 5′ and the width W2 of the slot 11e is set to a length equal to or greater than the width W1 of the removed portion 11g.

Because in such a case the heat dissipating portion 11b of the heat dissipating member 11 is integrally connected to the secondary lead frame member 5′ in the portions 11f adjacent to the slot 11e, removing the portions 11f adjacent to the slot 11e along with the resin burr S makes it possible to efficiently remove the resin burrs S, and to effectively prevent the deformation of the heat dissipating portion 11b during the removal of the resin burr.

At least a portion of the heat dissipating member 11 of the lead frame member utilized as the secondary lead frame member 5′ in the present embodiment may be imparted a shape that is symmetrical relative to a fold line extending in a predetermined direction. In this case, the heat dissipating member 11 may be provided with a portion serving as a lead pin in a location opposite the heat dissipating lead pin 11a relative to a fold line (for instance, the fold line “α” shown in FIG. 6). When this lead frame member is used, a solid state relay 100 having a heat dissipating member 11 such as the one shown in FIG. 6 can be obtained.

Moreover, in the lead frame member utilized as the secondary lead frame member 5′, the heat dissipating portion 11b may be provided with a through hole 12 used for inserting a screw or another fastening member. When this lead frame member is used, a solid state relay 100 such as the one shown in FIGS. 7a and 7b can be obtained.

Moreover, in the lead frame member utilized as the secondary lead frame member 5′, the heat dissipating portion 11b may be provided with a plurality of notches (grooves) 15a of a V-shaped cross section extending in a predetermined direction, as well as provided with a concave portion 15b formed as a depression in the thickness direction. In such a case, the lead frame member may be formed by stamping etc., which makes it possible to form the notches 15a of a V-shaped cross-section and the concave portion 15b with a high degree of accuracy. When this lead frame member is used, a solid state relay 100 having a heat dissipating member 11 such as the one shown in FIGS. 9a and 9b can be obtained.

Moreover, in the lead frame member utilized as the secondary lead frame member 5′, the lead pin exit position y on the power element lead pin exit side face 6c of the molded package 6 is preferably located away from the central position γ′ and toward the top face 6a of the package 6 in the height direction of the package 6, such that the connecting portion 11c between the heat-dissipating lead pin 11a and power element lead pin T2 is expanded in the height direction of the package 6. When this lead frame member is used, a solid state relay 100 such as the one shown in FIG. 11 can be obtained.

It should be noted that explanations in the present embodiment have been provided using a solid state relay as an example, the present invention can be applied to any arrangement as long as this arrangement is a power semiconductor device comprising at least a power element.

The present invention can be implemented in a variety of other forms without departing from its spirit or essential features. For this reason, the above-described embodiments are to all intents and purposes merely illustrative and should not be construed as limiting. The scope of the present invention is indicated by the claims and is not in any way restricted by the descriptions of the specification. Furthermore, all variations and modifications of the claims within the scope of equivalency fall within the purview of the present invention.

1. A power semiconductor device comprising a power element, a package encapsulating the power element with resin, a power element mounting portion used for mounting the power element, and a plurality of lead pins brought out of the package, including a power element lead pin brought out of the power element mounting portion,
wherein the power semiconductor device comprises a heat dissipating member having, adjacent the power element lead pin, a heat dissipating lead pin integrally connected to the power element lead pin and a heat dissipating portion integrally connected to the heat dissipating lead pin.

2. The power semiconductor device according to claim 1, wherein the lead pin configuration of the package is a DIP-type configuration and the heat dissipating member is arranged in an orientation that is substantially perpendicular to a top face of the package by bending a distal end of the power element lead pin toward a bottom. Lace of the package in a direction substantially perpendicular to the top face of the package.

3. The power semiconductor device according to claim 2, wherein the heat dissipating member is arranged in the substantially perpendicular orientation and is bent toward a side opposite the top face of the package.

4. The power semiconductor device according to claim 2, wherein the heat dissipating member is arranged in the substantially perpendicular orientation and is bent to a side opposite a power element lead pin side end face of the package adjoining a power element lead pin exit side face of the package.

5. The power semiconductor device according to claim 2, wherein the lead pin exit position on the power element lead pin exit side face of the package is located away from the central position and toward the top face of the package in a height direction of the package, thereby expanding the connecting portion between the heat-dissipating lead pin and the power element lead pin in the height direction of the package.

6. The power semiconductor device according to claim 3, wherein the lead pin exit position on the power element lead pin exit side face of the package is located away from the central position and toward the top face of the package in a height direction of the package, thereby expanding the connecting portion between the heat-dissipating lead pin and the power element lead pin in the height direction of the package.

7. The power semiconductor device according to claim 4, wherein the lead pin exit position on the power element lead pin exit side face of the package is located away from the central position and toward the top face of the package in a height direction of the package, thereby expanding the connecting portion between the heat-dissipating lead pin and the power element lead pin in the height direction of the package.

8. The power semiconductor device according to claim 1, wherein the heat dissipating portion is provided with a through-hole used for inserting a fastening member.

9. The power semiconductor device according to claim 1, wherein the heat dissipating portion is provided with a concave portion formed as a depression in the thickness direction.

10. The power semiconductor device according to claim 1, wherein the heat dissipating portion is provided with a plurality of notches of a V-shaped cross-section extending in a predetermined direction.

11. The power semiconductor device according to claim 1, wherein the heat dissipating member is folded over at a fold line extending in a predetermined direction such that the folded portions are overlapped.

12. The power semiconductor device according to claim 11, wherein the heat dissipating member is provided with a portion serving as a lead pin in a position opposite the heat dissipating lead pin relative to the fold line.

13. The power semiconductor device according to claim 11, wherein at least a portion of the heat dissipating member folded over at the fold line is used as a clipping portion possessing a clamping structure capable of clamping and holding a portion of an external heat dissipating member provided separately from the heat dissipating member.

14. The power semiconductor device according to claim 1 which constitutes a solid state relay comprising a light-emitting element converting electrical signals to optical signals and a light-receiving element converting the optical signals from the light-emitting element to electrical signals, with the package encapsulating the light-emitting element and light-receiving element with resin in an optically coupled relationship together with the power element.

15. An electronic device comprising the power semiconductor device according to claim 1.

16. A lead frame member used in a power semiconductor device comprising a power element, a package encapsulating the power element with resin, a power element mounting portion used for mounting the power element, and a plurality of lead pins brought out of the package, including a power element lead pin brought out of the power element mounting portion,
wherein the lead frame member comprises a heat dissipating member having, adjacent the power element lead pin, a heat dissipating lead pin integrally connected to the power element lead pin and a heat dissipating portion integrally connected to the heat dissipating lead pin.

17. A method of making a DIP-type power semiconductor device comprising a power element, a package encapsulating the power element with resin, a power element mounting portion used for mounting the power element, and a plurality of lead pins brought out of the package, including a power element lead pin brought out of the power clement mounting portion, the method comprising the steps of:
lead frame member preparation, which involves preparing a primary lead frame member and a secondary lead frame member used for mounting the power element, wherein a lead frame member comprising a heat dissipating member having, adjacent the power element lead pin, a heat dissipating lead pin integrally connected to the power element lead pin and a heat dissipating portion integrally connected to the heat dissipating lead pin is prepared as the secondary lead frame member;
lead frame member placement, which involves mounting the power element on the secondary lead frame member and arranging the primary and secondary lead frame members in an opposed relationship;
package molding, which involves molding the package by encapsulating the power element with resin; and
lead frame member finishing, which involves bending a distal end of the power element lead pin toward a bottom face of the package in a direction substantially perpendicular to a top face of the package such that the heat dissipating member is arranged in an orientation that is substantially perpendicular to the top face.

18. The method of making a power semiconductor device according to claim 17,
wherein a lead frame member provided with a slot and having the heat dissipating portion of the heat dissipating member integrally connected in portions adjacent to the slot is prepared as the secondary lead frame member in the lead frame member preparation step, and
a cutting step involving cutting the portions adjacent to the slot is further included subsequent to the packaged molding step and prior to the lead frame member finishing step.

19. An electronic device comprising the power semiconductor device according to claim 2.

20. An electronic device comprising the power semiconductor device according to claim 3.
